(19) United States
(12) Patent Application Publication
(10) Pub. No.: US 2025/0194425 A1
(43) Pub. Date: Jun. 12, 2025

(54) ACTUATOR, LIQUID EJECTION HEAD, AND METHOD FOR MANUFACTURING ACTUATOR

(71) Applicant: CANON KABUSHIKI KAISHA, Tokyo (JP)

(72) Inventor: YUTAKA SETOMOTO, Kanagawa (JP)

(21) Appl. No.: 18/974,100

(22) Filed: Dec. 9, 2024

(30) Foreign Application Priority Data
Dec. 11, 2023 (JP) 2023-208566

(51) Int. Cl. H10N 30/20; B41J 2/14; B41J 2/16; H10N 30/057; H10N 30/50; H10N 30/853; H10N 30/87

(52) U.S. Cl. CPC H10N 30/2048; B41J 2/14233; B41J 2/161; B41J 2/164; H10N 30/057; H10N 30/50; H10N 30/8554; H10N 30/877; B41J 2002/14241; B41J 2002/14258

(57) ABSTRACT

An actuator has a first electrode, a piezoelectric body, and a second electrode that are on a surface of a substrate in this order and an insulating film covering at least a side surface of the piezoelectric body. The actuator has a plurality of slanted surfaces slanted relative to the substrate at an end portion of a surface of the first electrode which is opposite from the substrate, and an angle between the substrate and a first slanted surface of the plurality of slanted surfaces which is farthest away from the substrate is smaller than an angle between the substrate and any other one of the slanted surfaces.

### BACKGROUND

### Field

The present disclosure relates to an actuator, a liquid ejection head, and a method for manufacturing the actuator.

### Description of the Related Art

An actuator using a piezoelectric body, which changes its shape upon application of an electric field, is used in various industrial products as a means for moving or vibrating an object slightly and accurately. For example, a piezoelectric body is used in a compact speaker, a hard disk drive, a printer (a liquid ejection apparatus), or the like. Some printers use a piezoelectric body in its liquid ejection head that ejects droplets. Such a liquid ejection head ejects a droplet by driving a piezoelectric body by applying an electric field thereto from an upper electrode and a lower electrode formed to sandwich the piezoelectric body from above and below. Also, in order to prevent breakage of a piezoelectric body which is driven, for example, the piezoelectric body may be formed to cover an end portion of the lower electrode which has a slanted surface (see, for example, Japanese Patent Laid-Open No. 2005-35282 (Literature 1)).

Forming a slanted surface at an end portion of the upper surface of a lower electrode like in Literature 1 is preferable because it improves coverability of an insulating film covering the lower electrode and the piezoelectric body. However, a portion of the piezoelectric body that covers the slanted surface of the lower electrode tends to have ununiform orientation. For this reason, a region of the piezoelectric body that overlaps with the slanted surface of the lower electrode may fail to be an effective region where the piezoelectric body can be driven as designed. Especially in a case where only one slanted surface is formed at an end portion of the upper surface of the lower electrode, making the slant angle of the slanted surface of the lower electrode small in order to improve the coverability of the insulating film increases the horizontal length of the slanted surface and therefore makes it likely for the piezoelectric body to have a narrow effective region where the piezoelectric body can be driven as designed. By contrast, making the end portion of the lower electrode perpendicular in shape in order not to shorten the effective region of the piezoelectric body lowers the coverability of the insulating film and therefore may lower the reliability of the actuator.

### SUMMARY

An actuator according to an aspect of the present disclosure has a first electrode, a piezoelectric body, and a second electrode that are on a surface of a substrate in this order and an insulating film covering at least a side surface of the piezoelectric body. The actuator has a plurality of slanted surfaces slanted relative to the substrate at an end portion of a surface of the first electrode which is opposite from the substrate, and an angle between the substrate and a first slanted surface of the plurality of slanted surfaces which is farthest away from the substrate is smaller than an angle between the substrate and any other one of the slanted surfaces.

Further features of the present disclosure will become apparent from the following description of exemplary embodiments with reference to the attached drawings.

### BRIEF DESCRIPTION OF THE DRAWINGS

FIG. 1 is a perspective view schematically showing a liquid ejection apparatus;

FIGS. 2A and 2B are schematic diagrams showing the flow channel configuration of a liquid ejection head;

FIG. 3 is a sectional view schematically showing an actuator;

FIG. 4 is a sectional view schematically showing an actuator;

FIG. 5 is a sectional view schematically showing an actuator;

FIG. 6 is a sectional view schematically showing an actuator;

FIGS. 7A to 7D are step-by-step sectional views illustrating a process of manufacturing an actuator;

FIGS. 8A and 8B are step-by-step sectional views illustrating a process of manufacturing the actuator;

FIGS. 9A to 9D are step-by-step sectional views illustrating a process of manufacturing an actuator; and

FIGS. 10A and 10B are step-by-step sectional views illustrating a process of manufacturing the actuator.

### DESCRIPTION OF THE EMBODIMENTS

Various exemplary embodiments, features, and aspects of the present disclosure are described in detail below with reference to the drawings attached hereto. Note that the embodiments below do not limit the matters of the present disclosure and that not all the combinations of features described in the embodiments below are necessarily essential as solutions provided by the present disclosure. Note that the same constituents are described using the same reference number.

### Embodiment 1

### Configuration of a Liquid Ejection Apparatus

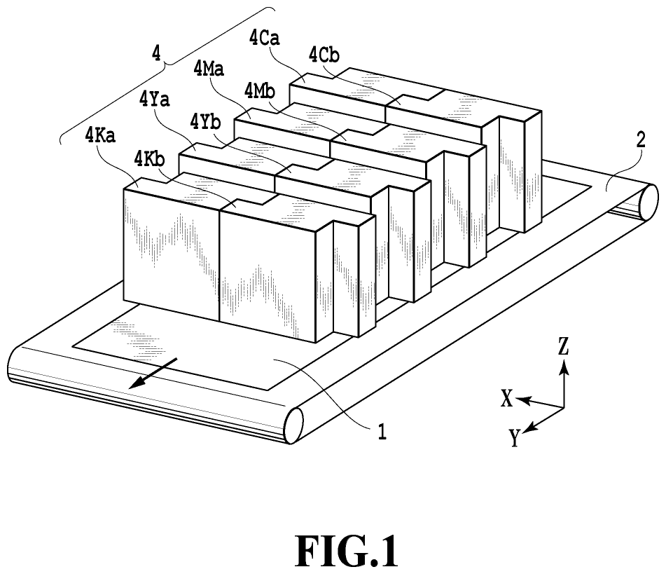

FIG. 1 is a perspective view schematically showing part of a liquid ejection apparatus (not shown). The liquid ejection apparatus of the present embodiment is a one-pass liquid ejection apparatus that prints an image on a print medium 1 with the print medium 1 moved once. The liquid ejection apparatus includes a liquid ejection head 4 as a full-line head having element substrates arrayed over the entire width of the print medium 1, the element substrates each having ejection ports to eject liquid. The print medium 1 is conveyed by a conveyance unit 2 in a direction indicated by an arrow (a +Y-direction) and is printed by the liquid ejection head 4. The liquid ejection head 4 of the present embodiment may be implemented in any mode, including the example shown in FIG. 1. In the example shown in FIG. 1, a liquid ejection apparatus having eight liquid ejection heads 4 (4Ka, 4Kb, 4Ya, 4Yb, 4Ma, 4Mb, 4Ca, and 4Cb) is shown. These eight liquid ejection heads 4 are positioned inside the liquid ejection apparatus by a reference member.

The liquid ejection head 4 of the present embodiment is, as described earlier, a one-pass head, or what is called a page-wide head, which is as long as the width of the print medium 1. Note that the width of the print medium 1 is a dimension measured in a direction (the X-direction) orthogonal to the direction in which the print medium 1 is conveyed. The liquid ejection head may be what is called a serial-type liquid ejection head, which performs printing on a print medium while the liquid ejection head is scanning. In an example configuration of a serial-type liquid ejection head, the liquid ejection head includes one element substrate for black ink and one element substrate for color ink. In another example configuration of a serial-type liquid ejection head, several element substrates are arranged so that ejection ports may overlap in the direction in which ejection port arrays are arrayed. In this configuration, the width of the liquid ejection head is narrower than the width of a print medium.

### Flow channel Configuration of the Liquid Ejection Head

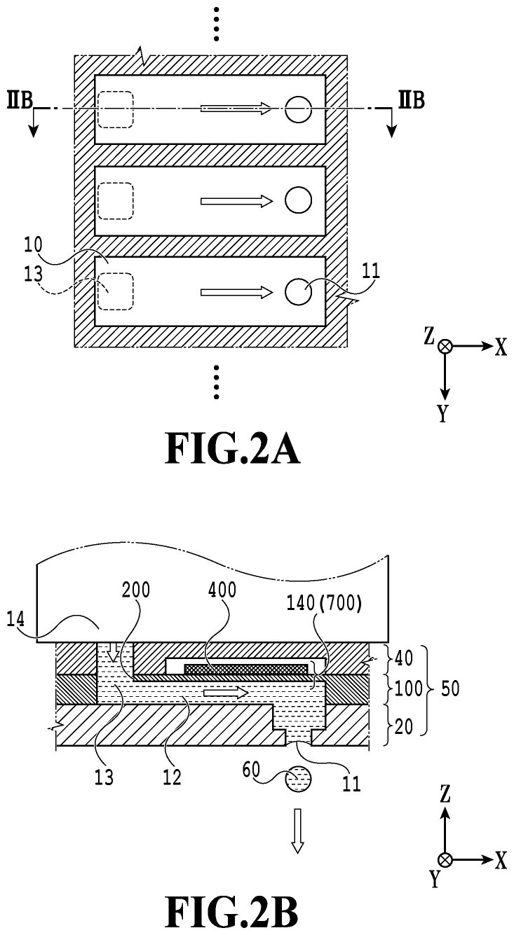

FIGS. 2A and 2B are schematic diagrams showing the flow channel configuration of an element substrate 50 of the liquid ejection head 4 of the present embodiment. FIG. 2A is a sectional view of the element substrate 50 seen from an ejection port 11 side of a flow channel block 10. FIG. 2B is a sectional view taken along IIB-IIB in FIG. 2A. The element substrate 50 includes three substrates (a first flow channel substrate 20, a second flow channel substrate 100, and a third flow channel substrate 40), and combining these substrates forms flow channels. As shown in FIG. 2A, the flow channel block 10 includes ejection ports 11 arrayed in the Y-direction as well as pressure chambers 12 and supply flow channels 13 prepared to communicate with the respective ejection ports 11. Each of the supply flow channels 13 is connected to a common liquid chamber 14 and supplies a liquid (hereinafter also referred to as ink) to the corresponding pressure chamber 12. The arrows in FIGS. 2A and 2B show the flow of the liquid (ink).

As shown in FIG. 2B, the element substrate 50 in the present embodiment is configured such that the first flow channel substrate 20, the second flow channel substrate 100, and the third flow channel substrate 40 are laminated in the Z-direction. The first flow channel substrate 20 is a substrate including the ejection ports 11 for ejecting ink. The second flow channel substrate 100 is a substrate where piezoelectric elements 140 and the pressure chambers 12 are formed. The third flow channel substrate 40 is a substrate that isolates piezoelectric bodies 400 of the piezoelectric elements 140 from ink and is also a substrate including flow channels through which ink is supplied from the common liquid chamber 14 to the pressure chambers 12.

The supply flow channel 13, the pressure chamber 12, and the ejection port 11 are formed in correspondence to each piezoelectric element 140. Adjacent pressure chambers 12 are partitioned from each other by a partitioning wall and are not directly affected by their adjacent piezoelectric elements 140. Note that the piezoelectric element 140 is formed adjacent to an insulating film 200 serving as a vibration plate.

In a stable state, ink housed in the pressure chamber 12 forms a meniscus at the ejection port 11. In the event where a voltage waveform is applied to the piezoelectric element 140 in accordance with an ejection signal, the piezoelectric element 140 deforms, allowing the pressure chamber 12 to expand or contract. By combining an expansion operation and a contraction operation, a droplet (ink droplet) 60 is generated from the meniscus and ejected in the −Z-direction.

After the ink in the pressure chamber 12 is consumed by the ejection operation, ink is supplied from the common liquid chamber 14 due to capillary action of the ejection port 11 and forms a meniscus again at the ejection port 11. Note that in the present embodiment, the ejection port 11, the piezoelectric element 140, and the pressure chamber 12 are together referred to as an ejection element.

Example specific dimensions of the above structure of the present embodiment are described. Ejection elements, i.e., the piezoelectric elements 140, the ejection ports 11, and the pressure chambers 12, are arrayed in the Y direction at a density of 150 nozzles per inch (npi). Each piezoelectric element 140 is approximately 500 micrometers (μm) in terms of its size in the X-direction (length) and approximately 110 μm in terms of its size in the Y-direction (width). The ejection port 11 is 25 μm in diameter and 30 μm in thickness, and the first flow channel substrate 20 is 100 μm in thickness. The pressure chamber 12 is 550 μm in terms of its size in the X-direction (length), 120 μm in terms of its size in the Y-direction (width), and 100 μm in terms of its size in the Z-direction (height). Also, the viscosity of ink used is 4 cp, and a minimum ink ejection amount from each ejection port 11 is 3 pl.

In the present embodiment, a drive frequency for each piezoelectric element 140 may be 30 KHz. Such a drive frequency can be set appropriately based on the time it requires for each ejection element to be refilled with new ink and be ready for the next ejection operation after actually ejecting ink upon application of a voltage to the piezoelectric element 140.

The liquid ejection head 4 is formed by an array of a plurality of element substrates each formed by an array of a plurality of ejection elements. Each element substrate is typically connected to a flexible wiring board (not shown) and is further connected to an electric wiring board (not shown). The electric wiring board has a power supply terminal for supplying power and a signal input terminal for receiving an ejection signal. Meanwhile, circulation flow channels (not shown) are formed in an ink supply unit (not shown) to supply each element substrate with ink containing a color material and supplied from an ink tank (not shown) and to collect ink not consumed in printing.

With the above-described configuration, based on print data inputted from the signal input terminal, each of the ejection elements disposed at the element substrate 50 ejects the ink supplied from the ink supply unit from the ejection port in the −Z-direction using the power supplied from the power supply terminal. Note that the dimensional values of each part described above are merely examples and may be changed as desired according to various specifications.

Examples of the liquid ejection head 4 of the liquid ejection apparatus include an inkjet printhead for a printer (an image printing apparatus). However, liquid ejected from the liquid ejection head 4 is not limited to ink. For example, the liquid ejection head 4 may eject a primer.

An actuator 700 configured such that the piezoelectric element 140 can deform by being driven is used in the liquid ejection head 4 of the liquid ejection apparatus. What is described in the present embodiment is the configuration of an actuator having a piezoelectric body with a large effective region and having high reliability by having a plurality of slanted surfaces formed at an end portion of the upper surface of a first electrode covered by the piezoelectric body. Note that an effective region of a piezoelectric body is, as described earlier, a region where a piezoelectric body can be driven (deformed) as designed.

### Configuration of the Actuator

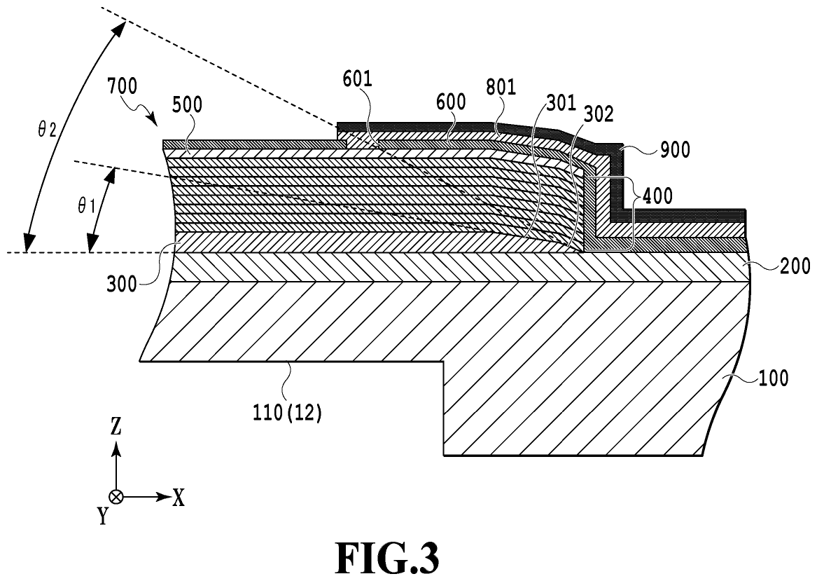

FIG. 3 is an enlarged sectional view schematically showing part of the actuator 700 of the present embodiment. To make it easier to understand the configuration of the actuator 700, FIG. 3 shows only the second flow channel substrate 100 of the element substrate 50 in a simplified manner.

As shown in FIG. 3, the actuator 700 of the present embodiment includes the insulating film 200, a first electrode 300, the piezoelectric body 400, a second electrode 500, and an insulating film 600. The insulating film 200, the first electrode 300, the piezoelectric body 400, the second electrode 500, and the insulating film 600 are laid in this order on one of the surfaces of the second flow channel substrate 100. The insulating film 600 covers at least the side surface of the piezoelectric body 400. Note that the first electrode 300, the piezoelectric body 400, and the second electrode 500 form the piezoelectric element 140 described above. At the surface of the second flow channel substrate 100 which is opposite from the actuator 700, a recess portion 110 for forming the pressure chamber 12 is formed. The piezoelectric body 400 is disposed to overlap with at least part of the recess portion 110. Also, the insulating film 200 formed on the upper surface of the second flow channel substrate 100 may be referred to as a substrate insulating film, and the insulating film 600 covering at least the side surface of the piezoelectric body 400 may be referred to as a piezoelectric-body insulating film.

Note that it is preferable that the second flow channel substrate 100 have a flat surface. A material to use for the second flow channel substrate 100 is appropriately selected from, for example, silicon, silicon carbide, quartz, gallium nitride, gallium arsenic, indium phosphorus, sapphire, and the like. To facilitate the formation of the recess portion 110, a silicon on insulator (SOI) wafer may be used as the second flow channel substrate 100. An SOI wafer has a silicon oxide layer formed on a silicon substrate and a silicon layer formed on the silicon oxide layer. A silicon oxide layer is also referred to as a buried oxide (BOX) layer. The layer thickness of the silicon oxide layer can be selected from between several tens of nanometers and several hundreds of micrometers. The layer thickness of the silicon layer can also be selected relatively freely. In a case where the layer thickness of the silicon oxide layer and the layer thickness of the silicon layer are appropriately combined and the silicon oxide layer is used as an etching stop layer, only the silicon layer can be removed by selective etching. Such etching produces the recess portion 110 whose bottom surface is the surface of the oxide silicon layer. This makes it possible to easily form the recess portion 110 having a very flat bottom surface.

The insulating film 200 is formed on the upper surface of the second flow channel substrate 100. A material usable for the insulating film 200 is, for example, a typical insulating material such as silica, silicon nitride, silicon oxynitride, alumina, or tetraethyl orthosilicate. Note that in a case where the material for the second flow channel substrate 100 is conductive, it is preferable that the insulating film 200 be formed between the first electrode 300 and the second flow channel substrate 100. Meanwhile, in a case where the material for the second flow channel substrate 100 is an insulator, the structure may be without the insulating film 200. In other words, in a case where the material for the second flow channel substrate 100 is an insulator, the actuator 700 does not have to have the insulating film 200. Note that in a case where the actuator 700 does not have the insulating film 200, the bottom part of the recess portion 110 of the second flow channel substrate 100 may function as a vibration plate.

The first electrode 300 is formed on the upper surface of the insulating film 200. The first electrode 300 is formed in the shape of a rectangle longer in the X-direction than in the Y-direction as seen from above the second flow channel substrate 100 (the Z-direction). Note that in a case where the material for the second flow channel substrate 100 is an insulator, the first electrode 300 may be formed on the upper surface of the second flow channel substrate 100. The first electrode 300 is also referred to as a lower electrode. The first electrode 300 may be exposed to a high temperature of several hundred degrees Celsius in the manufacturing process of the actuator 700. In this case, it is preferable that a material with a high melting temperature be used as a material for the first electrode 300. Examples of such a material include copper (Cu), platinum (Pt), gold (Au), chromium (Cr), cobalt (Co), and titanium (Ti). Also, examples of the material for the first electrode 300 include an alloy of copper, platinum, gold, chromium, cobalt, or titanium. The material for the first electrode 300 may be a multilayer body of any ones of copper, platinum, gold, chromium, cobalt, and titanium.

In a case where the piezoelectric body 400 is formed in contact with the upper surface of the first electrode 300, the first electrode 300 may serve also as a film for controlling the alignment of the crystalline orientation of the piezoelectric body 400. In this case, as a material for the first electrode 300, one having an appropriate crystal structure is selected as desired according to the material for the piezoelectric body 400. Note that a film for controlling the alignment of the crystalline orientation of the piezoelectric body 400 is also referred to as a crystalline orientation control film. For example, in a case where the material for the piezoelectric body 400 is lead zirconate titanate (PZT), platinum is preferably used as a material for the first electrode 300 serving also as a crystalline orientation control film. A typical film formation method such as magnetron sputtering can be used to form a film of the first electrode 300 using platinum as a material. In forming a film of the first electrode 300, the film thickness of the first electrode 300 is adjusted as desired so that the piezoelectric body 400 may attain desired orientation. In a case where the material for the first electrode 300 is platinum, as an adhesion layer for improving the strength of adhesion between the first electrode 300 and the insulating film 200, a layer of a multiplayer body of any ones of titanium, titanium oxide, and the like or a layer of an alloy of titanium, titanium oxide, or the like may be formed between the first electrode 300 and the insulating film 200.

Also, the first electrode 300 may be a multilayer body having an adhesion layer for improving the strength of adhesion to the insulating film 200 and a conductive layer laminated on the upper surface of the adhesion layer. In this case, a thin film of titanium, chromium, or the like can be used as a material for the adhesion layer, and a metal material such as copper, platinum, gold, chromium, cobalt, or titanium can be used as a material for the conductive layer. A material for the conductive layer may also be an alloy of copper, platinum, gold, chromium, cobalt, or titanium. As described earlier, in a case where the piezoelectric body 400 is formed in contact with the upper surface of the conductive layer, as the material for the conductive layer serving also as a crystal orientation control film, one having an appropriate crystal structure is selected as desired according to the material for the piezoelectric body 400.

A plurality of slanted surfaces, e.g., two slanted surfaces 301, 302, are formed at a +X-direction end portion of the upper surface of the first electrode 300. Note that a plurality of slanted surfaces are similarly formed at a +Y-direction end portion and a −Y-direction end portion of the upper surface of the first electrode 300. The plurality of slanted surfaces formed at the +Y-direction end portion and the −Y-direction end portion have the same configuration as those formed at the +X-direction end portion and are therefore neither shown nor described.

In the present embodiment, one of the two slanted surfaces 301, 302 which is farthest away from the second flow channel substrate 100 in the +Z-direction is referred to as a first slanted surface 301, and one of the two slanted surfaces 301, 302 which is second farthest away from the second flow channel substrate 100 in the +Z-direction is referred to as a second slanted surface 302. The angle between the first slanted surface 301 and the second flow channel substrate 100 is referred to as a first angle θ1, and the angle between the second slanted surface 302 and the second flow channel substrate 100 is referred to as a second angle θ2. Note that an angle between each slanted surface of the first electrode 300 and the second flow channel substrate 100 is an angle between the slanted surface of the first electrode 300 and a flat surface on the second flow channel substrate 100. For example, as shown in FIG. 3, an angle between each slanted surface of the first electrode 300 and the second flow channel substrate 100 may be an angle between the slanted surface of the first electrode 300 and the upper surface of the insulating film 200. An angle between each slanted surface of the first electrode 300 and the second flow channel substrate 100 may be an angle between the slanted surface of the first electrode 300 and the upper surface of the second flow channel substrate 100.

The first slanted surface 301 is formed as a flat surface extending long in the Y-direction. The first slanted surface 301 extends obliquely downward from an edge portion of a portion of the upper surface of the first electrode 300 which is parallel to the second flow channel substrate 100. The second slanted surface 302 is formed as a flat surface extending long in the Y-direction alongside the first slanted surface 301. The second slanted surface 302 extends obliquely downward from a lower edge portion of the first slanted surface 301. Also, the first angle θ1 is smaller than the second angle θ2. For example, the first angle θ1 is preferably 12 degrees or greater and 22 degrees or smaller, and the second angle θ2 is preferably 27 degrees or greater and 37 degrees or smaller.

The piezoelectric body 400 is formed on the upper surface of the first electrode 300, or in other words, on the surface of the first electrode 300 which is opposite from the insulating film 200 (the second flow channel substrate 100). The piezoelectric body 400 covers the upper surface of the first electrode 300 including the two slanted surfaces 301, 302. A portion of the piezoelectric body 400 that covers the two slanted surfaces 301, 302 extends along the two slanted surfaces 301, 302 and is therefore slanted relative to the second flow channel substrate 100. Lead zirconate titanate, capable of deforming a large amount, is mainly used as a material for the piezoelectric body 400. A piezoelectric material other than lead zirconate titanate can also be used as a material for the piezoelectric body 400. Examples of a piezoelectric material for the piezoelectric body 400 include barium titanate, lead titanate, lead metaniobate, bismuth titanate, zinc oxide, aluminum nitride, and potassium sodium niobate.

A film of the piezoelectric body 400 is formed using a typical film formation method such as sputtering, coating by spin coating, or the like. The thickness of the piezoelectric body 400 is preferably approximately 2 μm. In a case of forming a film of the piezoelectric body 400 through coating, the piezoelectric body 400 is formed by several layers. The piezoelectric body 400 is baked after the film formation of the piezoelectric body 400, so that the piezoelectric body 400 may have desired crystalline orientation. The temperature for baking the piezoelectric body 400 is selected as desired according to the piezoelectric material. In a case where the material for the piezoelectric body 400 is lead zirconate titanate, the temperature for baking the piezoelectric body 400 may be in the range from 600° C. to 900° C. After the piezoelectric body 400 is baked, etching such as wet etching or dry etching is performed to process the piezoelectric body 400 into a desired device shape. The position of the end portion of the piezoelectric body 400 formed by the etching may be on the plurality of slanted surfaces of the first electrode 300 or on the insulating film 200 beyond the +X-direction end portion of the first electrode 300. Also, the +X-direction end portion of the piezoelectric body 400 may cover the entirety or part of the plurality of slanted surfaces of the first electrode 300.

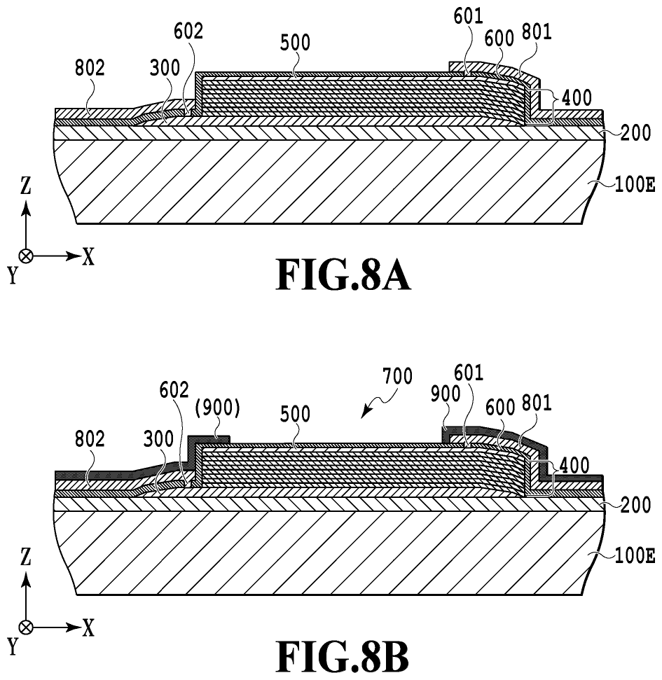

The second electrode 500 is formed on the upper surface of the piezoelectric body 400, or in other words, the surface of the piezoelectric body 400 which is opposite from the first electrode 300. A typical electrode material having conductivity can be used as a material for the second electrode 500. For example, a metal material such as aluminum (Al), tungsten (W), copper, titanium, chromium, gold, or platinum can be used as a material for the second electrode 500. In a case where the piezoelectric body 400 may bend because of internal stress in the first electrode 300 increased upon formation of the first electrode 300, the second electrode 500 may be given an internal stress in an opposite direction from that in the first electrode 300. This enables the second electrode 500 to have the function of cancelling out the stress exerted to the piezoelectric body 400. Examples of a material for the second electrode 500 that can give an internal stress in an opposite direction from that in the first electrode 300 include a titanium-tungsten alloy. Note that an upper wiring 801 is electrically connected to a +X-direction portion of the second electrode 500. A lower wiring 802 (see FIGS. 8A and 8B) is electrically connected to a portion of the first electrode 300 that protrudes beyond the piezoelectric body 400 in the −X-direction.

The insulating film 600 is formed to cover the upper surface of the second electrode 500, the side surface of the piezoelectric body 400, the upper surface of part of the first electrode 300, and the upper surface of part of the insulating film 200. The insulating film 600 is disposed between the upper wiring 801 and the second electrode 500, between the upper wiring 801 and the piezoelectric body 400, between the lower wiring 802 and the first electrode 300, and the upper wiring 801 (or the lower wiring 802) and the insulating film 200. Note that the insulating film 600 covers a portion of the upper surface of the first electrode 300 that protrudes beyond the piezoelectric body 400 in the −X-direction, including a plurality of surfaces formed at the −X-direction end portion of the upper surface of the first electrode 300. Also, in a case where the end portion of the piezoelectric body 400 covers part of the plurality of slanted surfaces of the first electrode 300, the insulating film 600 covers the rest of the plurality of slanted surfaces of the first electrode 300. In other words, the insulating film 600 covers a portion of the upper surface of the first electrode 300 which is not covered by the piezoelectric body 400. A material favorably used for the insulating film 600 is, similarly to the insulating film 200 formed on the upper surface of the second flow channel substrate 100, silica, silicon nitride, silicon oxynitride, alumina, tetraethyl orthosilicate, or the like. Also, the material for the insulating film 600 may be a multilayer film of any ones of silica, silicon nitride, silicon oxynitride, alumina, and tetraethyl orthosilicate. For example, the material for the insulating film 600 may be a multilayer film having an alumina film formed in contact with the second electrode 500 and the first electrode 300 and a silicon oxide film formed covering the alumina film.

In order for the piezoelectric body 400 to be displaced sufficiently, it is preferable that a potential difference applied between the second electrode 500 (the upper wiring 801) and the first electrode 300 (the lower wiring 802), i.e., a potential difference applied in the direction of the film thickness of the piezoelectric body 400 be approximately 30 V or greater. In a case of forming the piezoelectric body 400 using a semiconductor, a potential difference relatively large for a semiconductor device is applied in order to displace the piezoelectric body 400. Meanwhile, the breakdown electric field strength of the insulating film 600 is approximately 10 megavolts per centimeter (MV/cm). Thus, making the film thickness of the insulating film 600 30 nanometers (nm) or greater can reduce the probability of the actuator 700 breaking. In order to form the insulating film 600 thick enough not to cause breakdown with favorable productivity, chemical vapor deposition (CVD) or sputtering is typically used as a method for the film formation of the insulating film 600.

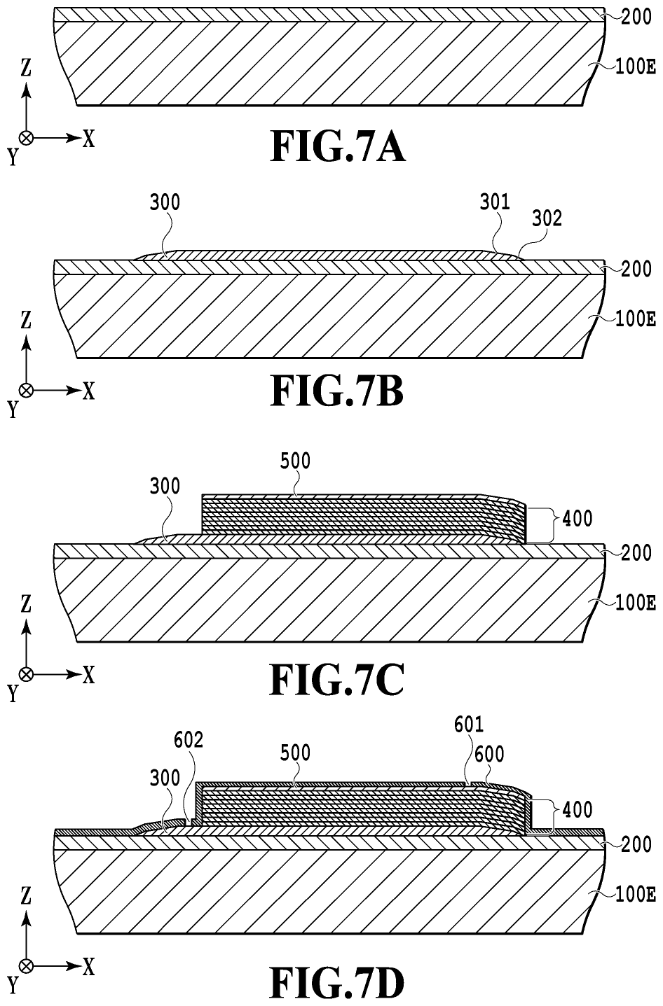

In order to displace the piezoelectric body 400 by applying a desired voltage to the second electrode 500 and the first electrode 300, the second electrode 500 is electrically connected to the upper wiring 801, and the first electrode 300 is electrically connected to the lower wiring 802. At a portion of the insulating film 600 which covers the second electrode 500, an upper through-hole 601 is formed, penetrating in the vertical direction (the Z-direction). One end of the upper wiring 801 is inserted through the upper through-hole 601 and is joined to the second electrode 500. At a portion of the insulating film 600 which covers the first electrode 300, the lower through-hole 602 (see FIG. 7D) is formed, penetrating in the vertical direction (the Z-direction). One end of the lower wiring 802 is inserted through the lower through-hole 602 and joined to the first electrode 300.

A typically used metal material can be used as a material for the upper wiring 801 and the lower wiring 802. For example, a metal material such as aluminum, copper, or gold can be used as a material for the upper wiring 801 and the lower wiring 802. Examples of a material for the upper wiring 801 and the lower wiring 802 include an alloy of aluminum, copper, or gold. Also, in order to improve the strength of adhesion of the upper wiring 801 and the lower wiring 802 to the insulating film 600, a thin film of titanium, chromium, or the like may be formed between the upper wiring 801 and the insulating film 600 and between the lower wiring 802 and the insulating film 600.

As described earlier, in order for the piezoelectric body 400 to be displaced sufficiently, a relatively high voltage is preferably applied to the second electrode 500 and the first electrode 300. Also, because of a high surface density of the plurality of actuators 700 provided at a chip-type liquid ejection head (the element substrate 50), in a case where current flows through the surface of the element substrate 50 under a high humidity environment, the actuator 700 may break. Thus, the upper wiring 801 and the lower wiring 802 are preferably covered by a passivation film 900 with high insulation properties. A material with high insulation properties such as silica, silicon nitride, or alumina is favorably used as a material for the passivation film 900. In the liquid ejection head, the passivation film 900 is preferably resistant to humidity. For example, a passivation film partly including a silicon nitride film is preferable because it has higher resistant to humidity than a passivation film formed of a silicon oxide film. Compared to a passivation film formed of a silicon oxide film, a passivation film partly including a silicon nitride film can have sufficient humidity resistance and insulating properties even in a case where the film thickness is small. Using a passivation film with humidity resistance can help prevent a high humidity environment from affecting the displacement performance of the piezoelectric body 400.

Note that it is difficult to planarize the upper wiring 801 and the lower wiring 802 formed on the upper surface of the insulating film 600 using chemical mechanical polishing (CMP) or the like because it may affect the displacement performance of the piezoelectric body 400. For this reason, a step shape based on the upper through-hole 601 appears at the surface of the upper wiring 801, and a step shape based on the lower through-hole 602 appears at the surface of the lower wiring 802. Thus, the passivation film 900 covers a step of 30 nm or greater generated at the portion of the upper wiring 801 which is inserted through the upper through-hole 601 and a step of 30 nm or greater generated at the portion of the lower wiring 802 which is inserted through the lower through-hole 602.

In the present embodiment, the first electrode 300 is processed into a suitable size according to the design. In that event, controlling the shape of the end portion of the first electrode 300 can improve the coverability of the insulating film 600 covering the side surface of the piezoelectric body 400 formed on the upper surface of the first electrode 300 and therefore expand the effective region of the piezoelectric body 400.

If the end portion of the first electrode 300 has a perpendicular structure, a void is likely to be generated at the step portion of the insulating film 600 covering the upper surface of the second electrode 500 and the +X-direction side surface of the piezoelectric body 400, which may lower the coverability of the insulating film 600 and may therefore lower reliability. A portion of the piezoelectric body 400 which is far from the second flow channel substrate 100 is displaced as a free end and therefore is displaced by a larger amount than a portion of the piezoelectric body 400 which is close to the second flow channel substrate 100. For this reason, in the event where the piezoelectric body 400 is driven, stress concentration is likely to occur at the piezoelectric body 400 and the insulating film 600.

In the present embodiment, a plurality of slanted surfaces, e.g., the two slanted surfaces 301, 302, are formed at an end portion of the upper surface of the first electrode 300. Because the insulating film 600 extends along the two slanted surfaces 301, 302 of the first electrode 300, a change in height is gentle at the step portion of the insulating film 600 covering the upper surface of the second electrode 500 and the +X-direction side surface of the piezoelectric body 400. The formation of the two slanted surfaces 301, 302 at an end portion of the upper surface of the first electrode 300 can improve the coverability of the insulating film 600 covering the +X-direction side surface of the piezoelectric body 400 and hence elevates reliability. The formation of the two slanted surfaces 301, 302 at the end portion of the upper surface of the first electrode 300 can also shorten the horizontal length of the two slanted surfaces 301, 302. This enables the region of the piezoelectric body 400 which overlaps with the two slanted surfaces 301, 302 to be smaller, which means a larger effective region for the piezoelectric body 400 and higher actuation efficiency for the piezoelectric body 400.

Also, the angle between the first slanted surface 301 and the second flow channel substrate 100 (the first angle θ1) is smaller than the angle between the second slanted surface 302 and the second flow channel substrate 100 (the second angle θ2). Because the slant angle of a slanted surface sequentially becomes larger toward the second flow channel substrate 100 with the slant angle of the first slanted surface 301 farthest away from the second flow channel substrate 100 being the smallest, stress concentration at the piezoelectric body 400 and the insulating film 600 upon driving of the piezoelectric body 400 can be mitigated. Also, because the slant angle of a slanted surface sequentially becomes larger toward the second flow channel substrate 100 with the slant angle of the first slanted surface 301 farthest away from the second flow channel substrate 100 being the smallest, the coverability of the portion of the piezoelectric body 400 which covers the two slanted surfaces 301, 302 can be improved. As described earlier, the first angle θ1 is preferably 12 degrees or greater and 22 degrees or smaller, and the second angle θ2 is preferably 27 degrees or greater and 37 degrees or smaller. This enables improvement in the coverability of the insulating film 600 covering the +X-direction side surface of the piezoelectric body 400 and shortening of the horizontal length of the two slanted surfaces 301, 302.

As thus described, according to the present embodiment, the actuator 700 having the piezoelectric body 400 with a large effective region and having high reliability can be provided. Specifically, according to the present embodiment, a plurality of slanted surfaces, i.e., the two slanted surfaces 301, 302, are formed at an end portion of the upper surface of the first electrode 300. The formation of the two slanted surfaces 301, 302 at an end portion of the upper surface of the first electrode 300 improves the coverability of the insulating film 600 covering the +X-direction side surface of the piezoelectric body 400 and therefore elevates reliability. The formation of the two slanted surfaces 301, 302 at an end portion of the upper surface of the first electrode 300 also shortens the horizontal length of the two slanted surfaces 301, 302. This makes the region of the piezoelectric body 400 that overlaps with the two slanted surfaces 301, 302 smaller, which means a larger effective region for the piezoelectric body 400 and higher actuation efficiency for the piezoelectric body 400. Also, the angle between the first slanted surface 301 and the second flow channel substrate 100 (the first angle θ1) is smaller than the angle between the second slanted surface 302 and the second flow channel substrate 100 (the second angle θ2). Because the slant angle of a slanted surface sequentially becomes larger toward the second flow channel substrate 100 with the slant angle of the first slanted surface 301 farthest away from the second flow channel substrate 100 being the smallest, stress concentration at the piezoelectric body 400 and the insulating film 600 upon driving of the piezoelectric body 400 can be mitigated. Also, because the slant angle of a slanted surface sequentially becomes larger toward the second flow channel substrate 100 with the slant angle of the first slanted surface 301 farthest away from the second flow channel substrate 100 being the smallest, the coverability of the portion of the piezoelectric body 400 which covers the two slanted surfaces 301, 302 can be improved. In this way, the actuator 700 having the piezoelectric body 400 with a large effective region and having high reliability can be provided.

Note that the two slanted surfaces 301, 302 may each be formed as a curved surface. In other words, the first slanted surface 301 may be formed as a curved surface, and the second slanted surface 302 may be formed as a curved surface. In this case, a border portion between the first slanted surface 301 and the second slanted surface 302 is a portion where the angle between a tangent plane to each slanted surface and the second flow channel substrate 100 changes discontinuously. Also, in this case, the first slanted surface 301 is formed as a curved surface shape which, on a section as seen in the Y-direction (an XZ-section), curves in a convex form. The second slanted surface 302 is formed as a curved surface shape which, on a section as seen in the Y-direction, curves in a convex form with a larger curvature than the first slanted surface 301. The angle between a tangent plane to the first slanted surface 301 and the second flow channel substrate 100 becomes smaller as a tangent point where the tangent plane to the first slanted surface 301 meets the first slanted surface 301 is farther away from the second flow channel substrate 100. The angle between a tangent plane to the second slanted surface 302 and the second flow channel substrate 100 becomes smaller as a tangent point where the tangent plane to the second slanted surface 302 meets the second slanted surface 302 is farther away from the second flow channel substrate 100.

This, like in the above embodiment, improves the coverability of the insulating film 600 covering the +X-direction side surface of the piezoelectric body 400 and shortens the horizontal length of the two slanted surfaces 301, 302. Also, because the slant angle of a slanted surface gradually becomes larger toward the second flow channel substrate 100 with the slant angle of the first slanted surface 301 farthest away from the second flow channel substrate 100 being the smallest, stress concentration at the passivation film 900 upon driving of the piezoelectric body 400 can be mitigated.

### First Modification

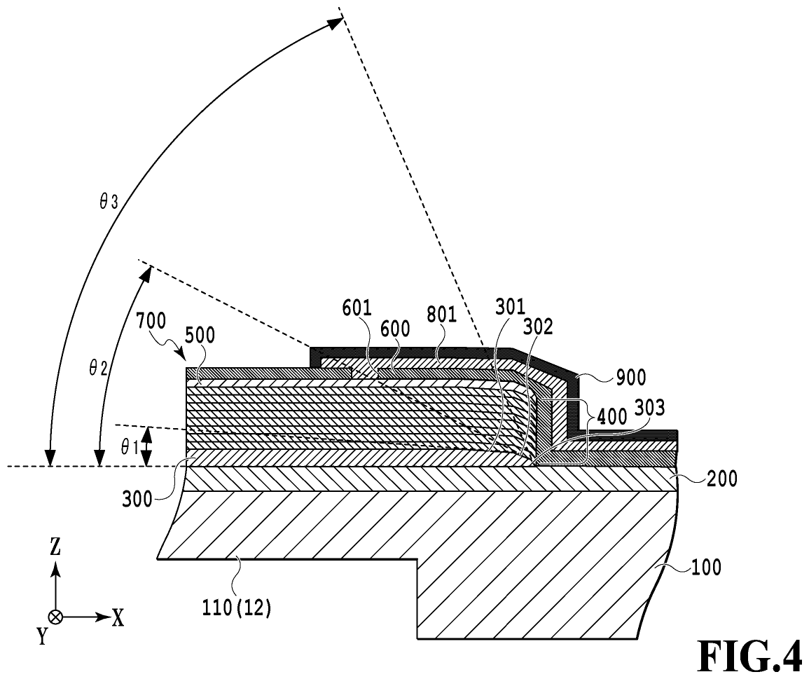

FIG. 4 is an enlarged sectional view schematically showing part of the actuator 700 of a first modification. The members in the first modification are configured similarly to those in the embodiment described above and are therefore described using the same reference numerals as those used for the members in the embodiment described above. In the first modification, as another example of the plurality of slanted surfaces, three slanted surfaces 301, 302, 303 are formed at the +X-direction end portion of the upper surface of the first electrode 300. Note that three slanted surfaces are formed at the +Y-direction end portion and the −Y-direction end portion of the upper surface of the first electrode 300 as well.

In the first modification, one of the three slanted surfaces 301, 302, 303 which is farthest away from the second flow channel substrate 100 in the +Z-direction is referred to as a first slanted surface 301. One of the three slanted surfaces 301, 302, 303 which is second farthest away from the second flow channel substrate 100 is referred to as a second slanted surface 302. One of the three slanted surfaces 301, 302, 303 which is third farthest away from the second flow channel substrate 100 is referred to as a third slanted surface 303. The angle between the first slanted surface 301 and the second flow channel substrate 100 is referred to as a first angle θ1, the angle between the second slanted surface 302 and the second flow channel substrate 100 is referred to as a second angle θ2, and the angle between the third slanted surface 303 and the second flow channel substrate 100 is referred to as a third angle θ3. Note that the angle between each slanted surface of the first electrode 300 and the second flow channel substrate 100 is, like in the above embodiment, an angle between the slanted surface of the first electrode 300 and a flat surface on the second flow channel substrate 100.

The first slanted surface 301 is formed as a flat surface extending long in the Y-direction. The first slanted surface 301 extends obliquely downward from an edge portion of a portion of the upper surface of the first electrode 300 which is parallel to the second flow channel substrate 100. The second slanted surface 302 is formed as a flat surface extending long in the Y-direction alongside the first slanted surface 301. The second slanted surface 302 extends obliquely downward from a lower edge portion of the first slanted surface 301. The third slanted surface 303 is formed as a flat surface extending long in the Y-direction alongside the first slanted surface 301 and the second slanted surface 302. The third slanted surface 303 extends obliquely downward from a lower edge portion of the second slanted surface 302. Also, the first angle θ1 is smaller than the second angle θ2 and the third angle θ3. In other words, the second angle θ2 is larger than the first angle θ1, and the third angle θ3 is larger than the second angle θ2. A portion of the piezoelectric body 400 which covers the three slanted surfaces 301, 302, 303 extends along the three slanted surfaces 301, 302, 303 and is therefore slanted relative to the second flow channel substrate 100.

According to the first modification, like in the above embodiment, the actuator 700 having the piezoelectric body 400 with a large effective region and having high reliability can be provided.

Also, the first angle θ1 is preferably 12 degrees or greater and 22 degrees or smaller. The second angle θ2 is 27 degrees or greater and 37 degrees or smaller. The third angle θ3 is preferably 67 degrees or greater and 77 degrees or smaller. This improves the coverability of the insulating film 600 covering the +X-direction side surface of the piezoelectric body 400 and shortens the horizontal length of the three slanted surfaces 301, 302, 303.

Note that the three slanted surfaces 301, 302, 303 may each be formed of a curved surface. In other words, the first slanted surface 301 may be formed as a curved surface, the second slanted surface 302 may be formed as a curved surface, and the third slanted surface 303 may be formed as a curved surface. In this case, portions where the angle between a tangent plane to each slanted surface and the second flow channel substrate 100 changes discontinuously are border portions between the first slanted surface 301 and the second slanted surface 302 and between the second slanted surface 302 and the third slanted surface 303. Also, in this case, the first slanted surface 301 is formed as a curved surface shape which, on a section as seen in the Y-direction (an XZ-section), curves in a convex form. The second slanted surface 302 is formed as a curved surface shape which, on a section as seen in the Y-direction, curves in a convex form with a larger curvature than the first slanted surface 301. The third slanted surface 303 is formed as a curved surface shape which, on a section as seen in the Y-direction, curves in a convex form with a larger curvature than the second slanted surface 302. The angle between a tangent plane to the first slanted surface 301 and the second flow channel substrate 100 becomes smaller as a tangent point where the tangent plane to the first slanted surface 301 meets the first slanted surface 301 is farther away from the second flow channel substrate 100. The angle between a tangent plane to the second slanted surface 302 and the second flow channel substrate 100 becomes smaller as a tangent point where the tangent plane to the second slanted surface 302 meets the second slanted surface 302 is farther away from the second flow channel substrate 100. The angle between a tangent plane to the third slanted surface 303 and the second flow channel substrate 100 becomes smaller as a tangent point where the tangent plane to the third slanted surface 303 meets the third slanted surface 303 is farther away from the second flow channel substrate 100.

This, like in the above embodiment, improves the coverability of the insulating film 600 covering the +X-direction side surface of the piezoelectric body 400 and shortens the horizontal length of the three slanted surfaces 301, 302, 303. Also, because the slant angle of a slanted surface gradually becomes larger toward the second flow channel substrate 100 with the slant angle of the first slanted surface 301 farthest away from the second flow channel substrate 100 being the smallest, stress concentration at the passivation film 900 upon driving of the piezoelectric body 400 can be mitigated.

Note that four or more slanted surfaces, e.g., four slanted surfaces, five slanted surfaces, or six slanted surfaces, may be formed at the +X-direction end portion of the upper surface of the first electrode 300. With N being an integer which is 3 or greater and k being an integer which is 2 or greater and N or smaller, the angle between the second flow channel substrate 100 and one of the N slanted surfaces which is k-th farthest away from the second flow channel substrate 100 is preferably larger than the angle between the second flow channel substrate 100 and one of the N slanted surfaces which is (k−1)-th farthest away from the second flow channel substrate 100.

### Second Modification

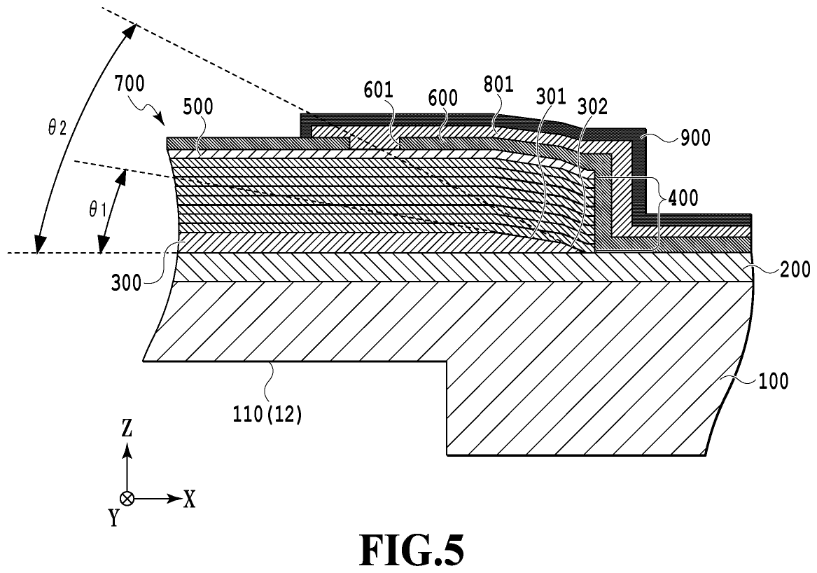

FIG. 5 is an enlarged sectional view schematically showing part of the actuator 700 of a second modification. The members in the second modification are configured similarly to those in the embodiment described above and are therefore described using the same reference numerals as those used for the members in the embodiment described above. As shown in FIG. 5, the piezoelectric body 400 of the second modification is formed extending onto the upper surface of the insulating film 200, beyond the +X-direction end portion of the first electrode 300.

According to the second modification, like the above embodiment, the actuator 700 having the piezoelectric body 400 with a large effective region and having high reliability can be provided.

Note that in a case where sputtering is used to form the piezoelectric body 400, a portion of the piezoelectric body 400 which covers the slanted surfaces of the first electrode 300 tends to be slanted relative to the second flow channel substrate 100 as shown in, for example, FIG. 3. This enables lowering of the step portion of the insulating film 600 over which the upper wiring 801 electrically connected to the second electrode 500 has to cross. Also, even in a case where sputtering is used to form the piezoelectric body 400, depending on the film formation conditions for the piezoelectric body 400 such as pressure and power, the end portion of the piezoelectric body 400 can be made to be close to being parallel to the second flow channel substrate 100.

### Third Modification

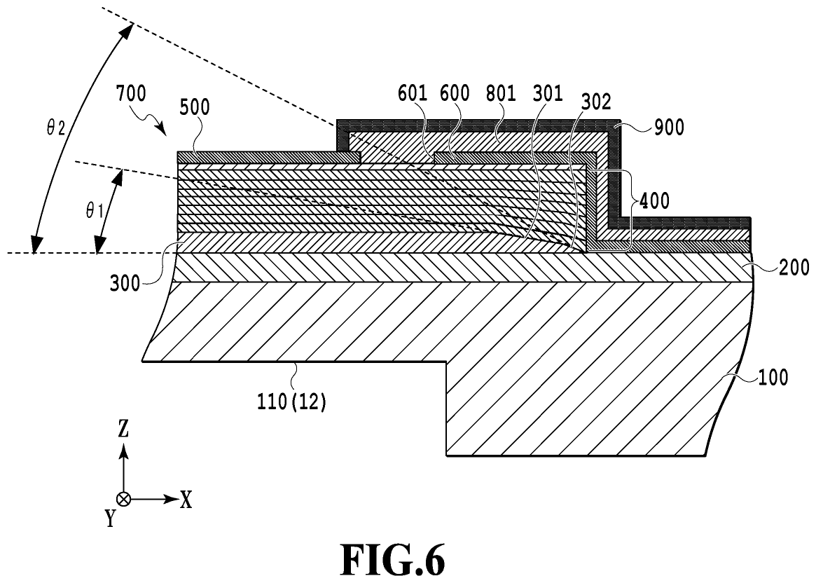

FIG. 6 is an enlarged sectional view schematically showing part of the actuator 700 of a third modification. The members in the third modification are configured similarly to those in the embodiment described above and are therefore described using the same reference numerals as those used for the members in the embodiment described above. The piezoelectric body 400 of the third modification is formed by spin coating. As shown in FIG. 6, in a case where spin coating is used to form the piezoelectric body 400, a portion of the piezoelectric body 400 which covers the slanted surfaces of the first electrode 300 tends to slant less relative to the second flow channel substrate 100 than in a case where sputtering is used to form the piezoelectric body 400. However, adjusting the number of coatings in spin coating, the thickness of the piezoelectric body 400, the viscosity of the piezoelectric body 400, and the like allows the end portion of the piezoelectric body 400 to be slanted relative to the second flow channel substrate 100, like in a case where sputtering is used to form the piezoelectric body 400. This facilitates the photolithography step and the etching step in the formation of the upper wiring 801 on the upper surface of the insulating film 600 located above the piezoelectric body 400, like in a case where sputtering is used to form the piezoelectric body 400.

According to the third modification, like the above embodiment, the actuator 700 having the piezoelectric body 400 with a large effective region and having high reliability can be provided.

In the above embodiment, of the first electrode 300 and the second electrode 500, only the first electrode 300 may be formed of platinum, or both of the first electrode 300 and the second electrode 500 may be formed of platinum.

Although the actuator 700 is used in the liquid ejection head 4 of an ejection liquid apparatus in the above embodiment, the present disclosure is not limited to this. For example, the actuator may be used in a speaker or a hard disk drive. Also, the actuator may be used in an autofocus mechanism in a portable camera module or in an anti-shake function in a digital camera.

### Examples

Next, specific examples of the actuator 700 are described using the drawings.

### Example 1

Example 1 is an example corresponding to the above embodiment. What is described in Example 1 is the configuration of and a method for manufacturing the actuator 700 for which sputtering is used to form the piezoelectric body 400. Note that the members in Example 1 are configured similarly to those in the embodiment described above and are therefore described using the same reference numerals as those used for the members in the embodiment described above.

FIGS. 7A to 8B are step-by-step sectional views illustrating a manufacturing process in Example 1. As shown in FIG. 7A, a substrate 100E made of single-crystal silicon was prepared as a raw material for the second flow channel substrate 100. The substrate 100E as a raw material for the second flow channel substrate 100 is hereinafter referred to simply as a substrate 100E. A silicon oxide film with a thickness of 500 nm was formed on the upper surface of the substrate 100E through a wet oxidation method using oxygen and hydrogen gas (O₂ and H₂ gas) to form the insulating film 200.

Next, as shown in FIG. 7B, the first electrode 300 was formed overlying the insulating film 200. In the formation of the first electrode 300, a first film as a raw material for the first electrode 300 was formed on the upper surface of the insulating film 200 by sputtering. After the film formation, a resist pattern was photolithographically formed to make a desired pattern for the first electrode 300, and the first electrode 300 was formed by dry etching. By dry etching, a plurality of slanted surfaces (e.g., the two slanted surfaces 301, 302) were formed at an end portion of the upper surface of the first electrode 300. Note that platinum was used as a material for the first electrode 300, and the thickness of the first electrode 300 was 100 nm. As an adhesion layer for improving the strength of adhesion between the first electrode 300 and the insulating film 200, a multilayer body of titanium and titanium oxide (not shown) was formed using sputtering.

Alternatively, the three slanted surfaces 301, 302, 303 may be formed at the end portion of the upper surface of the first electrode 300. In this case, for example, the first angle θ1 may be 17 degrees, the second angle θ2 may be 32 degrees, and the third angle θ3 may be 72 degrees.

Adjusting the etching conditions used in forming the first electrode 300 makes it possible to obtain a structure where the end portion of the upper surface of the first electrode 300 has a plurality of slanted surfaces which are either flat or curved. For example, the end portion of the upper surface of the first electrode 300 can be formed into a desired structure by depositing a reaction product on an etched surface of the first electrode 300 while setting back a resist during etching and adjusting etching conditions for a dry etching apparatus. The etching conditions depend on the configuration of the etching apparatus. For example, the etching conditions may be as follows: RF power, 400 W to 600 W; bias power, 100 W to 200 W; pressure, 0.3 Pa to 1.0 Pa; and gas used, a mixed gas of chlorine and argon.

Next, as shown in FIG. 7C, the piezoelectric body 400 was formed overlying the first electrode 300, and the second electrode 500 was formed overlying the piezoelectric body 400. The second electrode 500 and the piezoelectric body 400 are formed as follows. A film as a raw material for the piezoelectric body 400 was formed on the upper surface of the first electrode 300 using sputtering. Also, using sputtering, a second film as a raw material for the second electrode 500 was formed on the upper surface of the film as a raw material for the piezoelectric body 400. After the film formation, a resist pattern was photolithographically formed to make a desired pattern for the second electrode 500 and the piezoelectric body 400, and etching was performed to form the second electrode 500 and the piezoelectric body 400. Note that lead zirconate titanate was used as a material for the piezoelectric body 400, and the thickness of the piezoelectric body 400 was 2 μm. A titanium-tungsten alloy was used as a material for the second electrode 500, and the thickness of the second electrode 500 was 120 nm.

As a result, the piezoelectric element 140 (see FIG. 2B) formed by the first electrode 300, the piezoelectric body 400, and the second electrode 500 was formed. A portion of the piezoelectric body 400 (and the second electrode 500) which covers the slanted surfaces of the first electrode 300 is slanted relative to the substrate 100E. The border line for patterning of the piezoelectric body 400 may be on one of the slanted surfaces of the first electrode 300 or may be on the insulating film 200. The side surface of the piezoelectric body 400 formed by etching may be perpendicular to (the upper surface of) the substrate 100E as shown in FIG. 7C or may be slanted relative to the substrate 100E.

Next, as shown in FIG. 7D, the insulating film 600 with a thickness of 100 nm was formed on the upper side of the first electrode 300, the piezoelectric body 400, and the second electrode 500 using CVD. Also, a resist pattern was photolithographically formed to make a desired pattern for the upper through-hole 601 and the lower through-hole 602, and etching was performed to form the upper through-hole 601 and the lower through-hole 602 in the insulating film 600. Note that tetraethyl orthosilicate (TEOS) was used as a material for the insulating film 600. Also, the film thickness and the film formation conditions for the insulating film 600 may be determined considering that forming the first electrode 300 using dry etching removes part of the underlying insulating film 200.

Next, as shown in FIG. 8A, the upper wiring 801 and the lower wiring 802 were formed overlying the insulating film 600. In the formation of the upper wiring 801 and the lower wiring 802, a film as a raw material for the upper wiring 801 and the lower wiring 802 was formed on the upper surface of the insulating film 600 by sputtering. After the film formation, a resist pattern was photolithographically formed to make a desired pattern for the upper wiring 801 and the lower wiring 802, and etching was performed to form the upper wiring 801 and the lower wiring 802. As a result, the upper wiring 801 was electrically connected to the second electrode 500 through the upper through-hole 601 in the insulating film 600, and the lower wiring 802 was electrically connected to the first electrode 300 through the lower through-hole 602 in the insulating film 600.

Next, as shown in FIG. 8B, a silicon nitride film with a thickness of 50 nm was formed on the upper side of the upper wiring 801 and the lower wiring 802 using CVD to form the passivation film 900 with high insulation properties. In the formation of the passivation film 900, a resist pattern was photolithographically formed to make a desired pattern, and then etching was performed to form an opening portion only at a center part of a portion of the passivation film 900 which overlaps with the second electrode 500. This enables increasing humidity resistance and improves reliability of the upper wiring 801 and the lower wiring 802.

The actuator 700 of Example 1 is thus completed. Although not shown, next, the substrate 100E was processed to form the recess portion 110 for retaining ink, and the second flow channel substrate 100 was thus fabricated. Next, the first flow channel substrate 20 was joined to the lower surface side of the second flow channel substrate 100, and the third flow channel substrate 40 was joined to the upper surface side of the second flow channel substrate 100. A liquid ejection head including a plurality of the actuators 700 was thus fabricated. Then, as with a conventional liquid ejection head manufacturing method, mounting and assemblage of electric components, support members, and the like were performed for the liquid ejection head. A liquid ejection head unit was thus completed.

According to Example 1, the actuator 700 having the piezoelectric body 400 with a large effective region and having high reliability can be provided.

### Example 2

Example 2 is an example corresponding to the above embodiment. What is described in Example 2 is the configuration of and a method for manufacturing the actuator 700 for which spin coating is used to form the piezoelectric body 400. Note that the members in Example 2 are configured similarly to those in the embodiment described above and are therefore described using the same reference numerals as those used for the members in the embodiment described above.

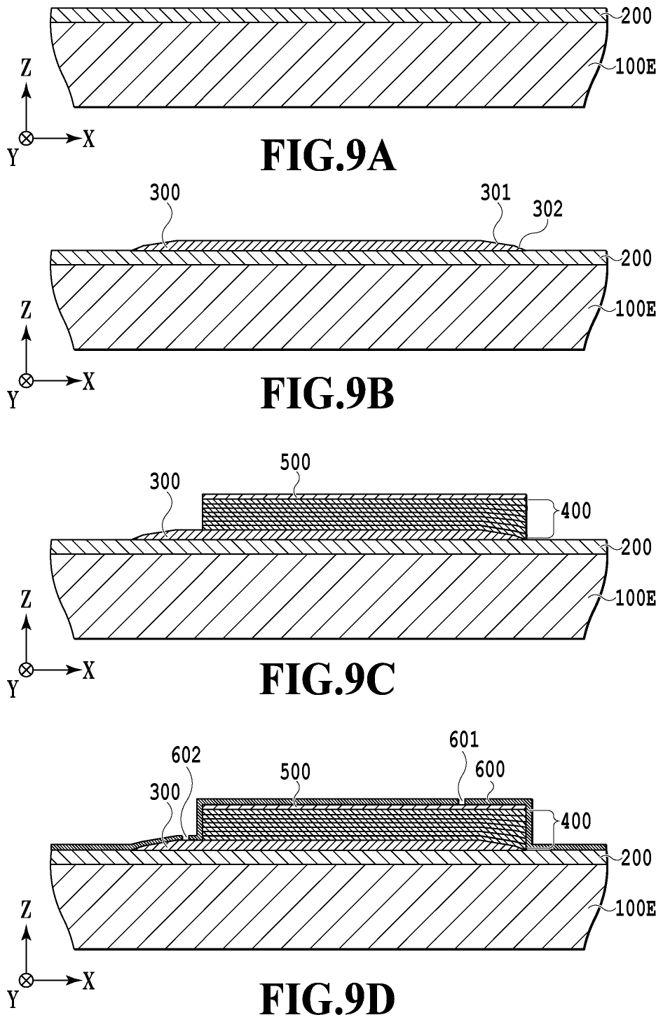

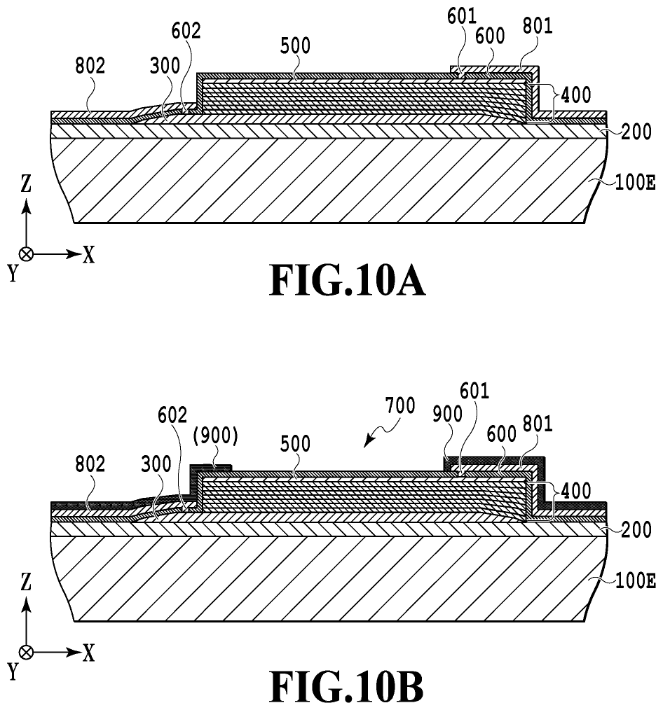

FIGS. 9A to 10B are step-by-step sectional views illustrating a manufacturing process in Example 2. As shown in FIG. 9A, a substrate 100E made of single-crystal silicon was prepared as a raw material for the second flow channel substrate 100. Like in Example 1, the insulating film 200 was formed on the upper surface of the substrate 100E.

Next, as shown in FIG. 9B, like in Example 1, the first electrode 300 was formed overlying the insulating film 200. In the formation of the first electrode 300, like in Example 1, a plurality of slanted surfaces (e.g., the two slanted surfaces 301, 302) were formed at an end portion of the upper surface of the first electrode 300.

Next, as shown in FIG. 9C, the piezoelectric body 400 was formed overlying the first electrode 300, and the second electrode 500 was formed overlying the piezoelectric body 400. The second electrode 500 and the piezoelectric body 400 were formed as follows. A film as a raw material for the piezoelectric body 400 was formed on the upper surface of the first electrode 300 using coating by spin coating and was baked at 800° C. to obtain desired crystalline orientation. Also, using sputtering, a second film as a raw material for the second electrode 500 was formed on the upper surface of the film as a raw material for the piezoelectric body 400. After the film formation, a resist pattern was photolithographically formed to make a desired pattern for the second electrode 500 and the piezoelectric body 400, and etching was performed to form the second electrode 500 and the piezoelectric body 400. Note that lead zirconate titanate was used as a material for the piezoelectric body 400, and the thickness of the piezoelectric body 400 was 2 μm. A titanium-tungsten alloy was used as a material for the second electrode 500, and the thickness of the second electrode 500 was 120 nm.

As a result, the piezoelectric element 140 (see FIG. 2B) formed by the first electrode 300, the piezoelectric body 400, and the second electrode 500 was formed. A portion of the piezoelectric body 400 (and the second electrode 500) which covers the slanted surfaces of the first electrode 300 was slanted relative to the substrate 100E more gently than in a case where the piezoelectric body 400 was formed by sputtering. The border line for patterning of the piezoelectric body 400 may be on one of the slanted surfaces of the first electrode 300 or may be on the insulating film 200. The side surface of the piezoelectric body 400 formed by etching may be perpendicular to (the upper surface of) the substrate 100E as shown in FIG. 9C or may be slanted relative to the substrate 100E.

Next, as shown in FIG. 9D, like in Example 1, the insulating film 600 with a thickness of 100 nm was formed on the upper side of the first electrode 300, the piezoelectric body 400, and the second electrode 500. In the formation of the insulating film 600, like in Example 1, the upper through-hole 601 and the lower through-hole 602 were formed in the insulating film 600.

Next, as shown in FIG. 10A, like in Example 1, the upper wiring 801 and the lower wiring 802 were formed overlying the insulating film 600. As a result, the upper wiring 801 was electrically connected to the second electrode 500 through the upper through-hole 601 in the insulating film 600, and the lower wiring 802 was electrically connected to the first electrode 300 through the lower through-hole 602 in the insulating film 600.

Next, as shown in FIG. 10B, like in Example 1, the passivation film 900 with high insulation properties was formed on the upper side of the upper wiring 801 and the lower wiring 802. In the formation of the passivation film 900, like in Example 1, an opening portion was formed only at a center part of a portion of the passivation film 900 which overlaps with the second electrode 500. This enables increasing humidity resistance and improves reliability of the upper wiring 801 and the lower wiring 802.

The actuator 700 of Example 2 was thus completed. Although not shown, next, the substrate 100E was processed to form the recess portion 110 for retaining ink, and the second flow channel substrate 100 was thus fabricated. Next, the first flow channel substrate 20 was joined to the lower surface side of the second flow channel substrate 100, and the third flow channel substrate 40 was joined to the upper surface side of the second flow channel substrate 100. A liquid ejection head including a plurality of the actuators 700 was thus fabricated. Then, as with a conventional liquid ejection head manufacturing method, mounting and assemblage of electric components, support members, and the like were performed for the liquid ejection head. A liquid ejection head unit was thus completed.

According to Example 2, the actuator 700 having the piezoelectric body 400 with a large effective region and having high reliability can be provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-208566, filed Dec. 11, 2023, which is hereby incorporated by reference wherein in its entirety.

What is claimed is:

1. An actuator comprising:
a first electrode, a piezoelectric body, and a second electrode that are on a surface of a substrate in this order and
an insulating film covering at least a side surface of the piezoelectric body, wherein
the actuator has a plurality of slanted surfaces slanted relative to the substrate at an end portion of a surface of the first electrode which is opposite from the substrate, and
an angle between the substrate and a first slanted surface of the plurality of slanted surfaces which is farthest away from the substrate is smaller than an angle between the substrate and any other one of the slanted surfaces.

2. The actuator according to claim 1, wherein
the first electrode contains platinum.

3. The actuator according to claim 1, wherein
a material for the piezoelectric body is lead zirconate titanate.

4. The actuator according to claim 1, wherein
the angle between the substrate and each one of the slanted surfaces decreases with distance from the substrate.

5. The actuator according to claim 1, wherein
the angle between the substrate and the first slanted surface is 12 degrees or greater and 22 degrees or smaller.

6. The actuator according to claim 1, wherein
an angle between the substrate and a second slanted surface of the plurality of slanted surfaces which is second farthest away from the substrate is 27 degrees or greater and 37 degrees or smaller.

7. The actuator according to claim 1, wherein
the plurality of slanted surfaces includes three slanted surfaces, and
an angle between the substrate and a third slanted surface of the three slanted surfaces which is third farthest away from the substrate is 67 degrees or greater and 77 degrees or smaller.

8. The actuator according to claim 1, wherein
the plurality of slanted surfaces includes three slanted surfaces,
an angle between the substrate and a second slanted surface of the three slanted surfaces which is second farthest away from the substrate is larger than the angle between the substrate and the first slanted surface, and
an angle between the substrate and a third slanted surface of the three slanted surfaces which is third farthest away from the substrate is larger than the angle between the substrate and the second slanted surface.

9. The actuator according to claim 1, wherein
each of the plurality of slanted surfaces is formed of a curved surface, and
an angle between the substrate and a tangent plane to the curved surface decreases as a tangent point where the tangent plane meets the curved surface is away from the substrate.

10. The actuator according to claim 1, wherein
the piezoelectric body covers at least part of the plurality of slanted surfaces.

11. The actuator according to claim 10, wherein
a portion of the piezoelectric body which covers at least part of the plurality of slanted surfaces is slanted relative to the substrate.

12. The actuator according to claim 1, wherein
the insulating film covers at least part of the plurality of slanted surfaces of the first electrode.

13. The actuator according to claim 1, wherein
the insulating film covers a surface of the second electrode which is opposite from the piezoelectric body.

14. The actuator according to claim 13, wherein
the insulating film has a through-hole for connecting a wiring to be electrically connected to the second electrode and the second electrode.

15. The actuator according to claim 1, wherein
a side surface of the first electrode is formed by the plurality of slanted surfaces.

16. A liquid ejection head that ejects liquid by driving an actuator having a first electrode, a piezoelectric body, and a second electrode that are on a surface of a substrate in this order and an insulating film covering at least a side surface of the piezoelectric body, wherein
the actuator has a plurality of slanted surfaces slanted relative to the substrate at an end portion of a surface of the first electrode which is opposite from the substrate, and
an angle between the substrate and a first slanted surface of the plurality of slanted surfaces which is farthest away from the substrate is smaller than an angle between the substrate and any other one of the slanted surfaces.

17. A method for manufacturing an actuator, the method comprising:
forming a film on a surface of a substrate;
forming a first electrode by dry-etching the film;
forming a piezoelectric body on the first electrode;
forming a second electrode on the piezoelectric body; and
forming an insulating film covering at least a side surface of the piezoelectric body, wherein
in the forming a first electrode, a plurality of slanted surfaces slanted relative to the substrate are formed at an end portion of a surface of the first electrode which is opposite from the substrate, and
an angle between the substrate and a first slanted surface of the plurality of slanted surfaces which is farthest away from the substrate is smaller than an angle between the substrate and any other one of the slanted surfaces.
